(19) United States
(12) Patent Application Publication
(10) Pub. No.: US 2026/0054772 A1
(43) Pub. Date: Feb. 26, 2026

(54) REDUNDANT INDUCTIVE RESOLVERS AND METHODS THEREOF

(71) Applicant: Ford Global Technologies, LLC, Dearborn, MI (US)

(72) Inventor: Jonathan Sullivan, Ferndale, MI (US)

(21) Appl. No.: 18/812,124

(22) Filed: Aug. 22, 2024

(51) Int. Cl. B62D 6/00; H05K 1/02

(52) U.S. Cl. CPC B62D 6/005; H05K 1/0243

(57) ABSTRACT

Disclosed examples include a printed circuit board (PCB) having a first power management circuit coupled to a first transmission coil; a second power management circuit; a first receiver coil including a first coil portion on a first layer of the PCB and a second coil portion on a second layer of the PCB; a second receiver coil including a third coil portion on the first layer of the PCB and a fourth coil portion on the second layer of the PCB, the second receiver coil in coaxial alignment with the first transmission coil and the first receiver coil.

### FIELD OF THE DISCLOSURE

This disclosure relates generally to sensor systems and, more particularly, to redundant inductive resolvers and methods thereof.

### BACKGROUND

Vehicles include multiple subsystems to carry out various functions. A steering subsystem enables a vehicle operator to control the direction of movement of the vehicle. In a mechanical steering subsystem, a steering shaft extends from a steering wheel to a rack and pinion assembly or a steering box system between the two front wheels of the vehicle. As the vehicle operator turns or rotates the steering wheel, the rotational motion is transferred through the steering shaft and translated into a linear movement by the rack and pinion assembly or the steering box system. The linear movement controls a steering direction of the two front wheels.

### SUMMARY

An example apparatus includes a printed circuit board (PCB), the PCB including a first power management circuit coupled to a first transmission coil, a second power management circuit, a first receiver coil including a first coil portion on a first layer of the PCB and a second coil portion on a second layer of the PCB, and a second receiver coil including a third coil portion on the first layer of the PCB and a fourth coil portion on the second layer of the PCB, the second receiver coil in coaxial alignment with the first transmission coil and the first receiver coil.

An example apparatus includes a printed circuit board (PCB), the PCB including first and second power management circuits coupled to respective first and second processors, a first receiver coil in circuit with the first processor, the first receiver coil including a first coil portion on a first layer of the PCB and a second coil portion on a second layer of the PCB, and a second receiver coil in circuit with the second processor and in coaxial alignment with the first receiver coil, the second receiver coil including a third coil portion on the first layer of the PCB and a fourth coil portion on the second layer of the PCB.

An example vehicle includes a target coupled to a steering shaft, a printed circuit board (PCB) in a steer-by-wire system, the PCB including first and second power management circuits coupled to respective first and second analog-to-digital converters, a first receiver coil including a first coil portion on a first layer of the PCB and a second coil portion on a second layer of the PCB, the first receiver coil coupled to the first analog-to-digital converter, and a second receiver coil including a third coil portion on the first layer of the PCB and a fourth coil portion on the second layer of the PCB, the second receiver coil in coaxial alignment with the first receiver coil, the second receiver coil coupled to the second analog-to-digital converter.

### BRIEF DESCRIPTION OF THE DRAWINGS

FIG. 1 is a perspective view of a vehicle in which an example redundant inductive resolver is implemented as part of a steer-by-wire (SBW) system.

FIG. 2 is a system diagram of an example implementation of a SBW system including a redundant inductive resolver.

FIG. 3 is a diagram of an example printed circuit board (PCB) having multiple transmission coils and receiver coils to implement the redundant inductive resolver of FIG. 2.

FIG. 4 is a diagram of the example redundant inductive resolver of FIG. 2 including redundant processors, power management circuits, and analog-to-digital converters on the PCB of FIG. 3.

FIG. 5 is a diagram of the target of FIG. 2 positioned in electromagnetic proximity of the PCB of FIGS. 3 and 4 and in coaxial alignment with the transmission and receiver coils of FIG. 3 to implement the redundant inductive resolver of FIGS. 2 and 4.

In general, the same reference numbers will be used throughout the drawings and accompanying written description to refer to the same or like parts. The figures are not necessarily to scale.

### DETAILED DESCRIPTION

Examples disclosed herein generally relate to using inductive resolver sensors to measure angular or rotational positions in a hand-wheel actuator (HWA) subsystem and a road-wheel actuator (RWA) subsystem of a vehicle's SBW system. In a SBW system, a HWA subsystem is coupled to a steering wheel and a RWA subsystem is coupled closer to the road-wheels. For example, the HWA subsystem receives driver inputs (e.g., steering inputs) via steering sensors, communicates the driver inputs to the RWA, and receives road surface and road-wheel feedback (e.g., vehicle handling feedback) from the RWA to return to the driver. A RWA subsystem converts a driver's inputs (e.g., steering inputs) from the HWA into road-wheel actuation, determines road-wheel feedback via road-wheel handling sensors, and communicates the feedback to the HWA. Back-up sensors can be used to provide redundancy on the HWA subsystem and RWA subsystem.

Unlike prior solutions, examples disclosed herein implement redundant inductive resolver sensors on the same PCB to provide redundancy in sensor operation. For example, if an operational status of an inductive resolver sensor on a PCB transitions to an offline, unavailable, or standby state, the other one of the inductive resolver sensors on the PCB can be used to provide steering control for the vehicle. In addition, inductive resolver sensors are significantly less affected by stray electromagnetic field (EMF) interference than hall effect sensors. Inductive resolver sensors are implemented using inductive coils in a coaxial and annular arrangement. These coils are printed directly on a single PCB on multiple layers or surfaces. For example, the single PCB includes two transmission coils and four to six receiver coils (e.g., sensing coils), or any other suitable number of receiver coils, on one or more layers of the PCB. Of the multiple receiver coils, groups of two or three receiver coils are treated as separate inductive resolver sensors. For example, for a total of four receiver coils on a PCB, a first group of two receiver coils implements a first inductive resolver sensor and a second group of two receiver coils implements a second inductive resolver sensor. Alternatively, for a total of six receiver coils on a PCB, the receiver coils can be grouped into two sets of three receiver coils such that each group of three receiver coils forms a corresponding inductive resolver sensor for a total of two inductive resolver sensors. In any case, examples disclosed herein may be implemented using any other suitable number of receiver coils and transmission coils on a PCB and any other suitable number of receiver coils per inductive resolver sensor.

In examples disclosed herein, each inductive resolver sensor is connected to a corresponding processor chip (e.g., a digital signal processor (DSP), a general-purpose processor, an application specific integrated circuit (ASIC), a field programmable gate array (FPGA), or any other suitable programmable circuit) on the same PCB. A rotating target having multiple poles or lobes is placed in electromagnetic proximity to the PCB in a manner that coaxially aligns the target with the inductive resolver sensors. As used herein, electromagnetic proximity means that the target is sufficiently close to the inductive resolver sensors so that the target can affect or interrupt electromagnetic eddy currents generated in the inductive resolver sensors. The target is attached to a steering wheel through a steering shaft of which a rotational position is measured.

The poles or lobes of the target include a metallic material to make changes to an electromagnetic field resulting from the transmission coils. For example, the transmission coils of the PCB create EMFs that are affected, interrupted, or shaped by the polls or lobes of the rotating target. Based on such interrupting or shaping by the rotation of the rotating target, eddy currents are induced in the receiver coils of the inductive resolver sensors with variations based on the shaping of the EMFs. In turn, the receiver coils generate corresponding waveform signals. The waveform signals are used by the processing chips to calculate the rotational position of the rotating target. Each inductive resolver sensor is provided with a respective, independent power management circuit. As such, if an operational status of one inductive resolver sensor or its processor chip switches to an offline, unavailable, or standby state, the other inductive resolver sensor can continue operating, thereby allowing a vehicle operator to maintain control of the vehicle.

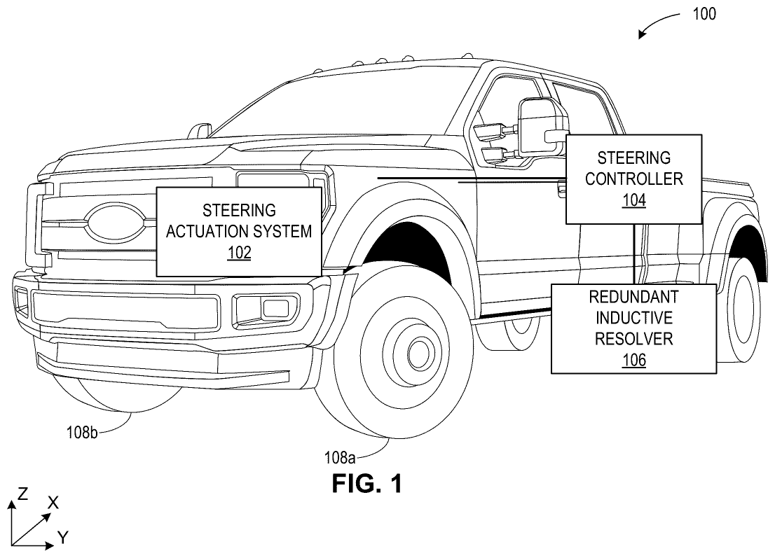

FIG. 1 is a perspective view of a vehicle 100 in which examples disclosed herein can be implemented. In the illustrated example of FIG. 1, the vehicle 100 includes an example steering actuation system 102, an example steering controller 104, and an example redundant inductive resolver 106. The vehicle 100 is a wheel-driven vehicle. In the illustrated example of FIG. 1, the vehicle 100 is a pick-up truck. In other examples, the vehicle 100 can be any type of wheeled vehicle (e.g., a sedan, a coupe, a van, a sports utility vehicle, an all-terrain vehicle (ATV), farming equipment, etc.). In some examples, the vehicle 100 includes an internal combustion engine (e.g., a non-electrified vehicle, a partially electrified vehicle, etc.). In other examples, the vehicle 100 is a fully electric vehicle.

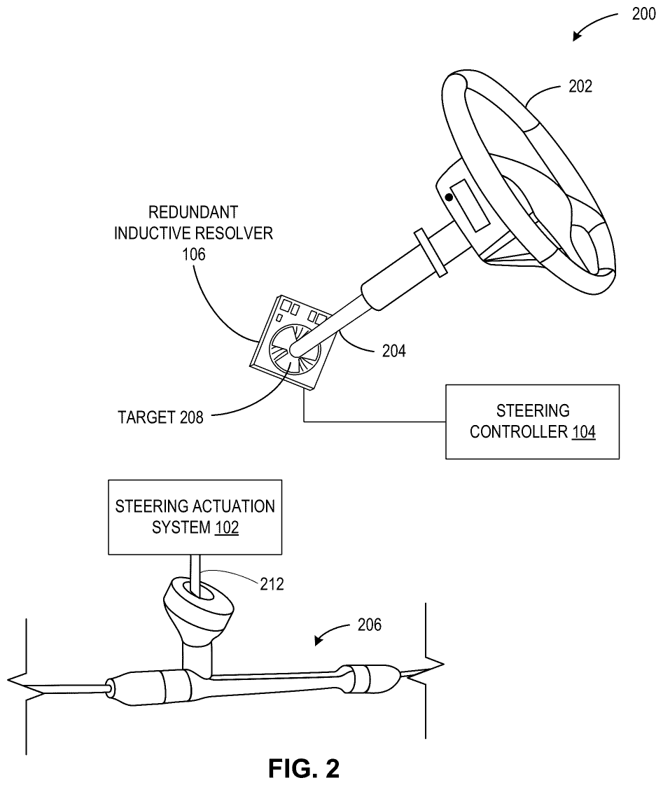

In example FIG. 1, the steering actuation system 102 and the steering controller 104 implement a SBW system (e.g., the SBW system 200 of FIG. 2). The steering actuation system 102 allows a user of the vehicle 100 to control/steer front wheels 108a, b of the vehicle 100. In other examples, the steering actuation system 102 allows a user of a vehicle 100 to also control/steer rear wheels of a four-wheel steer vehicle 100. In the illustrated example of FIG. 1, the steering actuation system 102 and the steering controller 104 include corresponding communication interfaces to communicate control information and feedback between the steering actuation system 102 and the steering controller 104.

The steering controller 104 controls and/or manages the steering actuation system 102. For example, the steering controller 104 can calculate a rotational angle of the steering actuation system 102 based on a rotational angle of a steering wheel controlled by a vehicle operator. In some examples, some or all of the steering controller 104 can be implemented by an electronic control unit (ECU) of the vehicle 100. In other examples, the steering controller 104 can be implemented by another suitable computer (e.g., another computer of the vehicle 100, a mobile device of a user of the vehicle 100, a remote computer, etc.).

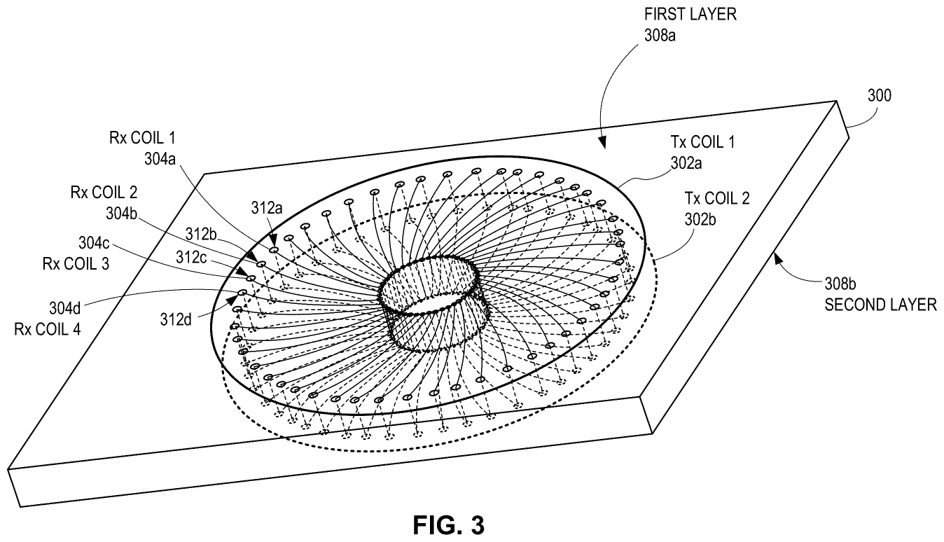

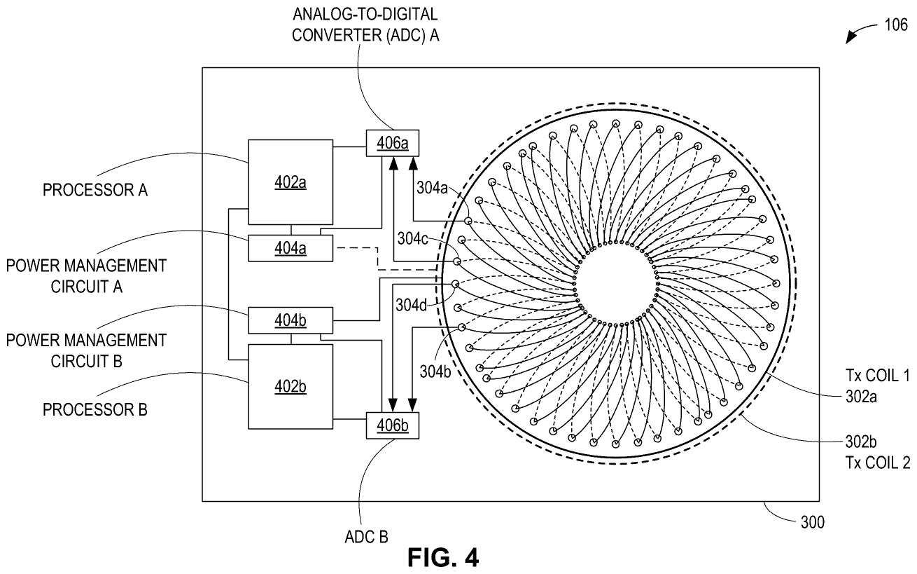

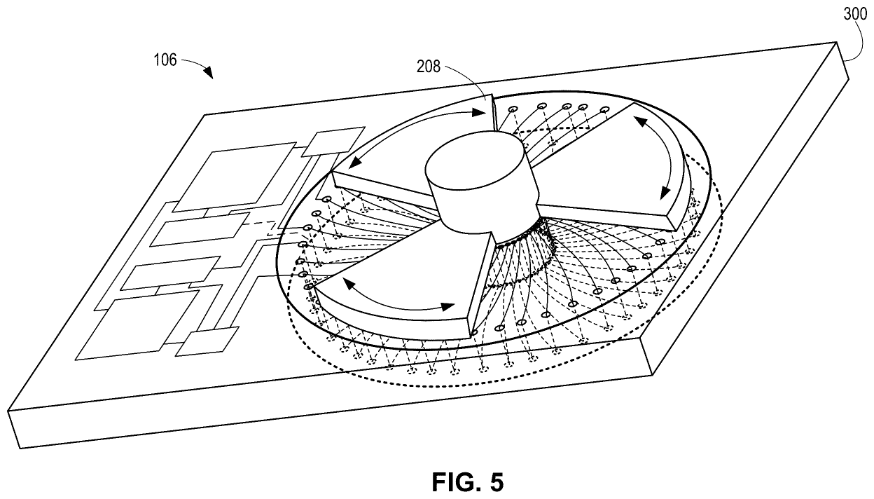

The steering controller 104 is in circuit with the redundant inductive resolver 106. The redundant inductive resolver 106 includes multiple receiver coils in a coaxial formation, as described below in connection with FIGS. 3 and 4. The redundant inductive resolver 106 measures a rotational angle of a steering wheel based on a target (e.g., the example target 208 of FIG. 2) that rotates proximate to the redundant inductive resolver 106, as described below in connection with FIG. 5. For example, the redundant inductive resolver 106 can be used to measure an angle of rotation of the steering wheel, a direction of rotation of the steering wheel, and a speed of rotation of the steering wheel, etc. In examples disclosed herein, angle of rotation, rotational angle, rotational position, and angular position are used interchangeably to refer to positions of a steering wheel, and a corresponding target, as a vehicle operator turns the steering wheel to steer the vehicle 100.

FIG. 2 is a system diagram of an example SBW system 200 that includes the steering actuation system 102, the steering controller 104, and the redundant inductive resolver 106 of FIG. 1. The SBW system 200 includes an example steering wheel 202, an example steering shaft 204, an example rack and pinion system 206, and an example target 208. The rack and pinion system 206 is coupled to the front wheels 108a,b of the vehicle 100 (FIG. 1). In other examples, the rack and pinion system 206 is coupled to the rear wheels of a four-wheel steer vehicle 100. In the example of FIG. 2, the steering controller 104 and the redundant inductive resolver 106 implement a HWA subsystem of the SBW system 200. Also in example FIG. 2, the steering actuation system 102 implements a RWA subsystem of the SBW system 200.

The steering wheel 202 allows a user of the vehicle 100 to operate the steering actuation system 102 and thereby steer the vehicle 100. To do so, the steering controller 104 is in communication with the steering actuation system 102. For example, the steering controller 104 includes a transceiver (e.g., a wireless or wired transceiver) that is in communication with a transceiver (e.g., a wireless or wired transceiver) of the steering actuation system 102. As such, the steering controller 104 can transmit driver inputs (e.g., rotating the steering wheel 202) from the steering wheel 202 as steering control signals (e.g., steering commands) to the steering actuation system 102 and the steering controller 104 can receive vehicle handling feedback from the steering actuation system 102. The steering wheel 202 includes an interface (e.g., handgrips, etc.) that enables a user to apply torque to the steering shaft 204 to turn the target 208. As the user turns the steering wheel 202, the rotational torque of the steering wheel is transferred through the steering shaft 204 to the target 208.

In the illustrated example of FIG. 2, the steering shaft 204 is coupled to the target 208 and the target 208 is positioned in electromagnetic proximity to the redundant inductive resolver 106. As used herein, electromagnetic proximity means that the target 208 is sufficiently close to the redundant inductive resolver 106 so that the target 208 can affect or interrupt electromagnetic eddy currents induced in receiver coils of the redundant inductive resolver 106, as described below in connection with FIG. 5. For example, a face of the target 208 may be positioned within 0.03 to 0.2 inches of a surface of the redundant inductive resolver 106. Although the target 208 is shown coupled to the steering shaft 204 in FIG. 2, in other examples, the steering shaft 204 may be omitted and the target 208 may be coupled to the steering wheel 202 via a steering column or directly to the steering wheel 202.

The target 208 includes multiple lobes and metallic material. For example, the target 208 may be constructed so that the lobes are solid metal or are coated with a metallic layer. In this manner, the target 208 can interact with an electric field generated by the redundant inductive resolver 106. For example, when power is applied to the redundant inductive resolver 106, it creates an electric field. When the target 208 rotates, the lobes of the target 208 interfere with the pattern of the electric field. The redundant inductive resolver 106 senses these electric field interruptions and generates corresponding signals representative of rotational positions of the target 208. Such rotational positions are representative of the rotational positions of the steering wheel 202. In this manner, the signals generated by the redundant inductive resolver 106 can be used by the steering controller 104 to transmit steering control signals to the steering actuation system 102. In addition to determining steering angle of the steering wheel 202, the redundant inductive resolver 106 may be used to derive other steering-related metrics such as steering velocity, steering acceleration, steering torque, etc. As described in more detail below, the redundant inductive resolver 106 includes redundant processors (e.g., the redundant processors 402a,b of FIG. 4). Cross-communication between such redundant processors may be used to increase accuracies of steering angle estimations.

The rack and pinion system 206 is a linear actuator that includes a pinion engaged with a rack. The rack and pinion system 206 translates rotational inputs from the steering actuation system 102 into linear motion to steer the wheels 108a,b (FIG. 1). In this manner, a user operating the steering wheel 202 causes the rack and pinion system 206 to change directions of the vehicle 100 by steering the wheels 108a, b.

Although not shown, the steering actuation system 102 also includes a redundant inductive resolver substantially similar or identical to the redundant inductive resolver 106 and a target substantially similar or identical to the target 208. The target can be coupled to a wheel-steering shaft 212, which is coupled to the rack and pinion system 206.

Based on such a configuration, the steering actuation system 102 can use its redundant inductive resolver and target to detect road-wheel feedback (e.g., vehicle handling feedback) from the wheels 108a, b and communicate that road-wheel feedback to the steering controller 104 so that the steering controller 104 can provide the feedback to a driver via the steering wheel 202.

Although the target 208 is described as being coupled to the steering shaft 204 (or to the wheel-steering shaft 212), in other examples, the target 208 can be coupled to a motor shaft and the redundant inductive resolver 106 can be used to measure the rotational positions of the motor shaft during operation of a corresponding motor. For example, such a motor could be used in the vehicle 100 (FIG. 1) to generate road torque feedback on the HWA without the motor being directly coupled to the steering shaft 204. Instead, the road torque feedback is transferred from the motor through a gear set or belt to the steering shaft 204. In examples where motor control is prioritized and the redundant inductive resolver 106 is being used for motor control as well as steering control, the redundant inductive resolver 106 may be placed on the motor shaft instead of directly on the steering shaft 204. In this manner, the redundant inductive resolver 106 can be used to measure rotational positions of the steering shaft 204 transferred through the gear set or belt to the motor shaft and the motor can be concurrently used to generate road torque feedback transferred through the motor shaft to the steering shaft 204 through the gear set or belt.

FIG. 3 is a diagram of an example PCB 300 having multiple transmission coils 302a, b and receiver coils 304a-d to implement the redundant inductive resolver 106 of FIG. 2. The PCB 300 includes an example first layer 308a and an example second layer 308b. In other examples, the PCB 300 may include any other suitable number of layers.

In the illustrated example of FIG. 3, the PCB 300 includes an example first transmission coil 302a and an example second transmission coil 302b. The PCB 300 also includes an example first receiver coil 304a having a first coil portion on the first layer 308a of the PCB 300 and a second coil portion on the second layer 308b of the PCB 300. In examples disclosed herein, different portions of a coil formed on different layers or surfaces of the PCB 300 are interconnected using vertical interconnect accesses or vias. For example, the PCB 300 of FIG. 3 includes an example first via 312a extending between the first layer 308a and the second layer 308b. The first via 312a electrically couples the first coil portion with the second coil portion of the first receiver coil 304a. The PCB 300 also includes an example second receiver coil 304b having a third coil portion on the first layer 308a of the PCB 300 and a fourth coil portion on the second layer 308b of the PCB 300. The PCB 300 includes an example second via 312b extending between the first layer 308a and the second layer 308b of the PCB 300. The second via 312b electrically couples the third coil portion with the fourth coil portion of the second receiver coil 304b.

As noted above, the PCB 300 may be implemented to include any suitable number of layers. The transmission coils 302a, b are implemented on respective layers of the PCB 300. In some examples, the PCB 300 includes third and fourth layers in addition to the first and second layers 308a, b, and the transmission coils 302a, b are implemented on respective ones of the third and fourth layers. In other examples, the first transmission coil 302a may be implemented on the first layer 308a and the second transmission coil 302b may be implemented on the second layer 308b. In such examples, the layouts of the transmission coils 302a, b are arranged to allow for PCB traces to be routed between circuitry components (e.g., the analog-to-digital converters (ADCs) 406a, b of FIG. 4) outside the transmission coils 302a, b and the receiver coils 304a-d without those PCB traces short-circuiting with the transmission coils 302a, b.

As shown in FIG. 3, the first and second receiver coils 304a, b are formed in a spiral pattern or spiral formation, creating an outer circumference and an inner circumference. The first and second vias 312a,b described above are located along the outer circumference of the spiral pattern. Additional vias are also located at other parts of the outer circumference and at the inner circumference to electrically connect additional portions of the first receiver coil 304a to one another and additional portions of the second receiver coil 304b to one another. Such vias are used to weave the first and second receiver coils 304a, b in alternating fashion between the first layer 308a and the second layer 308b of the PCB 300 so that the first and second receiver coils 304a,b can be arranged coaxially with one another and overlap without electrically shorting with one another. Although a particular spiral pattern is shown in FIG. 3 by way of example, other coaxial patterns may additionally or alternatively be used to implement receiver coils for use with examples disclosed herein.

In the example of FIG. 3, the PCB 300 also includes an example third receiver coil 304c having a fifth coil portion on the first layer 308a of the PCB 300 and a sixth coil portion on the second layer 308b of the PCB 300. An example third via 312c extending between the first layer 308a and the second layer 308b of the PCB 300 electrically couples the fifth coil portion with the sixth coil portion of the third receiver coil 304c. The PCB 300 also includes an example fourth receiver coil 304d including a seventh coil portion on the first layer 308a of the PCB 300 and an eighth coil portion on the second layer 308b of the PCB 300. An example fourth via 312d extending between the first layer 308a and the second layer 308b of the PCB 300 electrically couples the seventh coil portion with the eighth coil portion of the third receiver coil 304c. In the example of FIG. 3, the transmission coils 302a, b and the receiver coils 304a-d are in coaxial alignment with one another on the PCB 300.

Although multiple receiver coils are described above as being implemented across the first layer 308a and the second layer 308b, in other examples, the different receiver coils may be formed across more than two layers of the PCB 300. For example, the first receiver coil 304a and the second receiver coil 304b may be implemented across the first layer 308a and the second layer 308b, and the third receiver coil 304c and the fourth receiver coil 304d may be implemented across third and fourth layers of the PCB 300. In yet other examples, each of the receiver coils 304a-d may be implemented across a respective pair of layers in the PCB 300. In such examples, the PCB 300 includes eight layers for the four receiver coils 304a-d. Examples disclosed herein may be implemented using any suitable number of layers in the PCB 300 to implement multiple receiver coils and/or multiple transmission coils.

FIG. 4 is a diagram of the redundant inductive resolver 106 of FIG. 2 including example redundant processors 402a, b, example redundant power management circuits 404a,b, and example redundant ADCs 406a,b on the PCB 300 of FIG. 3. An example first power management circuit 404a is coupled to an example first processor 402a, an example first ADC 406a, and the first transmission coil 302a. An example second power management circuit 404b is coupled to an example second processor 402b, an example second ADC 406b, and the second transmission coil 302b. The redundant components are provided so that if a power management circuit, processor, or ADC goes to an offline, unavailable, or standby mode in one set of the redundant components, the other set of components can be used to control steering of the vehicle 100.

The power management circuits 404a, b are provided to receive input voltage to generate output voltages supplied to corresponding ones of the processors 402a, b and the ADCs 406a, b. The ADCs 406a, b are provided to convert analog signals from the receiver coils 304a-d to digital signals and to provide those digital signals to corresponding ones of the processors 402a, b. The first processor 402a is coupled to the first receiver coil 304a and the third receiver coil 304c via the first ADC 406a. The second processor 402b is coupled to the second receiver coil 304b and the fourth receiver coil 304d via the second ADC 406b.

The processors 402a, b may be implemented using any suitable processor circuit or controller circuit including, for example, DSPs, general-purpose processors, ASICs, FPGAs, or any other suitable programmable circuit. The processors 402a, b may execute machine-readable instructions to perform processes that determine rotational positions of the steering wheel 202 (FIG. 2) based on waveforms generated by the receiver coils 304a-d and that generate corresponding steering control signals or commands for transmission to the steering actuation system 102.

The power management circuits 404a, b may be implemented using discrete components or integrated circuit (IC) chips to receive input voltage and generate multiple voltage rails to power corresponding ones of the processors 402a, b, the ADCs 406a, b, and the transmission coils 302a, b. For example, each power management circuit 404a, b may be implemented in a respective IC chip having input pins to receive one or more input supply voltages and one or more control inputs from corresponding ones of the processors 402a, b. Each IC chip may also include output pins to drive supply voltages. In addition, although the ADCs 406a, b are shown separate from the power management circuits 404a, b, in other examples, the ADCs 406a, b are implemented in the power management circuits 404a, b.

FIG. 5 shows the target 208 positioned in electromagnetic proximity of the PCB 300 of FIGS. 3 and 4 in coaxial alignment with the transmission coils 302a, b (FIGS. 3 and 4) and the receiver coils 304a-d (FIGS. 3 and 4) to implement the redundant inductive resolver 106. The target 208 includes three lobes in a radial arrangement. In other examples, the target 208 may include fewer or more lobes to achieve a desired level of accuracy in determining steering parameters such as angle of rotation of the steering wheel, a direction of rotation of the steering wheel, and a speed of rotation of the steering wheel, etc.

In some examples, the first receiver coil 304a and the third receiver coil 304c form a first inductive resolver sensor coupled to the first processor 402a and the second receiver coil 304b and the fourth receiver coil 304d form a second resolver sensor coupled to the second processor 402b. In such examples, the first processor 402a receives waveform signal pairs generated by the first receiver coil 304a and the third receiver coil 304c based on angular positions of the target 208 relative to the first receiver coil 304a and the third receiver coil 304c. In addition, the second processor 402b receives waveform signal pairs generated by the second receiver coil 304b and the fourth receiver coil 304d based on the angular position of the target 208 relative to the second receiver coil 304b and the fourth receiver coil 304d. For example, the first power management circuit 404a provides a supply voltage to the first transmission coil 302a and the second power management circuit 404b provides another supply voltage to the second transmission coil 302b. These supply voltages cause the first transmission coil 302a and the second transmission coil 302b to generate corresponding EMFs that induce eddy currents in the receiver coils 304a-d. Upon rotation of the steering wheel 202 (FIG. 2) by a vehicle operator, the rotational motion is transferred via the steering shaft 204 to the target 208. This causes the target 208 to rotate proximate to the transmission coils 302a, b and the receiver coils 304a-d of the redundant inductive resolver 106. In other examples, instead of the first and third receiver coils 304a, c forming a first inductive resolver sensor and the second and fourth receiver coils 304b, d forming a second inductive resolver sensor, the first and second receiver coils 304a, b may form a first inductive resolver sensor coupled to the first processor 402a and the second and fourth receiver coils 304b, d may form a second inductive resolver sensor coupled to the second processor 402b. Further yet, an inductive resolver sensor may be implemented using any suitable combination of coils.

Rotating the target 208 through different angular or rotational positions varies the EMFs generated by the transmission coils 302a, b. In turn, these EMF variations change the electromagnetic eddy currents induced in the receiver coils 304a-d. The receiver coils 304a-d generate corresponding analog voltage signal waveforms representative of variations in the eddy currents and provide the analog voltage signal waveforms to corresponding ones of the ADCs 406a,b. The ADCs 406a,b convert the analog signals to digital signals. The ADCs 406a, b provide the digital signals to corresponding ones of the processors 402a, b. The waveforms of the digital signals are representative of the angular or rotational positions of the target 208 relative to the receiver coils 304a-d based on variations in the eddy currents. The processors 402a,b analyze the digital signals received from corresponding ones of the ADCs 406a,b to determine rotational positions of the steering wheel 202 and generate steering control signals to be transmitted to the steering actuation system 102 (FIGS. 1 and 2).

The receiver coils 304a-d can be arranged in the PCB 300 in a phase shifted arrangement from one another. This allows the processors 402a,b to compare waveform signals from pairs of the receiver coils 304a-d and cancel higher order harmonics between a pair of coils in an inductive receiver sensor to increase estimation accuracies of rotational positions of the steering wheel 202. As shown in FIG. 4, the processors 402a,b are communicatively coupled to one another. In this manner, the processors 402a,b can operate cooperatively to determine rotational positions of the steering wheel 202 based on waveform signals from the first inductive resolver sensor (e.g., the first receiver coil 304a and the third receiver coil 304c) and the second inductive resolver sensor (e.g., the second receiver coil 304b and the fourth receiver coil 304d). For example, the phase angle between the first inductive resolver sensor and the second inductive resolver sensor can be altered such that with communication between both processors 402a,b for each sensor, the raw data from one sensor can be used to cancel out higher order harmonics in the other sensor. Such process can be used to increase the estimation accuracy of the rotational position of the steering wheel 202.

As noted above, in some examples, the first receiver coil 304a and the third receiver coil 304c form a first inductive resolver sensor and the second receiver coil 304b and the fourth receiver coil 304d form a second resolver sensor. In other examples, three or more receiver coils can be integrated into corresponding ones of multiple layers of the PCB 300 and used to form an inductive resolver sensor and provide three or more concurrent signals to a corresponding processor 402a,b. For example, the first receiver coil 304a, the third receiver coil 304c, and one or more additional receiver coil(s) may operate as a first inductive resolver sensor in circuit with the first processor 402a, and the second receiver coil 304b, the fourth receiver coil 304d, and one or more additional receiver coil(s) may operate as a second inductive resolver sensor in circuit with the second processor 402b.

When the target 208 rotates based on steering input at the steering wheel 202, the first receiver coil 304a, the third receiver coil 304c, and one or more additional receiver coil(s) operate as the first inductive resolver sensor to concurrently generate three or more analog signals corresponding to an angular position of the target 208. In addition, the second receiver coil 304b, the fourth receiver coil 304d, and one or more additional receiver coil(s) operate as the second inductive resolver sensor to concurrently generate three analog signals corresponding to the angular position of the target 208. As such, the first processor 402a can use three or more digital signals concurrently generated based on the three or more receiver coils of a corresponding inductive resolver sensor to generate steering control signals for the steering actuation system 102. In addition, the second processor 402b can use an additional three or more digital signals concurrently generated based on three or more receiver coils of a corresponding second inductive resolver sensor to generate steering control signals for the steering actuation system 102. In such examples, three receiver coils in a single inductive resolver sensor can be phase shifted by 60 degrees from each other to allow a corresponding one of the processors 402a,b to compare relative magnitudes between the waveform signals received from the three receiver coils and cancel up to third order harmonics. Examples disclosed herein may also be used to cancel higher order harmonics depending on phase angles between inductive resolver sensors in the redundant inductive resolver 106 and the number of receiver coils implemented in the redundant inductive resolver 106.

The first ADC 406a converts the two analog signals from the first receiver coil 304a and the third receiver coil 304c to generate two digital signals and provides the digital signals to the first processor 402a. Similarly, the second ADC 406b converts the two analog signals from the second receiver coil 304b and the fourth receiver coil 304d to generate two digital signals and provides the digital signals to the second processor 402b. The processors 402a,b analyze their corresponding pairs of digital signals to determine rotational positions of the steering wheel 202 and generate steering control signals to be transmitted to the steering actuation system 102. For example, each processor 402a,b can average its pair of digital signals to filter out noise or outlier data points and generate an averaged or filtered digital signal to serve as the basis for its steering control.

In yet other examples, more than two receiver coils may be used to implement an inductive resolver sensor. For example, a first inductive resolver sensor corresponding to the first processor 402a may be implemented by three or more receiver coils and a second inductive resolver sensor corresponding to the second processor 402b may be implemented by another three or more receiver coils.

The transmission coils 302a,b and the receiver coils 304a-d implement multiple levels of redundancy so that if an operational status of any of the coils 302a,b and 304a-d transitions to an offline, unavailable, or standby state, operational ones of the transmission coils 302a,b and the receiver coils 304a-d can be used to provide steering control for the vehicle 100. For example, the first transmission coil 302a and the second transmission coil 302b on the same PCB 300 operate redundantly so that if an operational status of either of the first transmission coil 302a or the second transmission coil 302b changes to an offline, unavailable, or standby state, the other one of the first transmission coil 302a or the second transmission coil 302b can be used to provide steering control for the vehicle 100. In addition, a first inductive resolver sensor (e.g., the first receiver coil 304a and/or the third receiver coil 304c) and a second inductive resolver sensor (e.g., the second receiver coil 304b and/or the fourth receiver coil 304d) on the same PCB 300 operate redundantly so that if an operational status of either of the inductive resolver sensors changes to an offline, unavailable, or standby state, the other one of the inductive resolver sensors on the same PCB 300 can be used to provide steering control for the vehicle 100.

In addition, for a single resolver sensor including three or more receiver coils (e.g., the first receiver coil 304a, the third receiver coil 304c, etc.), when the three or more receiver coils are in an operational state, the single resolver sensor concurrently outputs three or more analog signals corresponding to the number of operational receiver coils to, for example, the first ADC 406a. As such, the first processor 402a can determine rotational positions of the steering wheel 202 based on the three or more concurrent signals. In the event that an operational status of a receiver coil changes to an offline, unavailable, or standby state, at least two of the still operational receiver coils (e.g., the first receiver coil 304a and the third receiver coil 304c) can still be used to provide steering control for the vehicle 100. As such, examples disclosed herein can be used to provide redundancy across multiple receiver coils in a single resolver sensor.

In addition, in the above examples describe both of the processors 402a,b concurrently analyze digital signals to determine rotational positions of the steering wheel 202 and generate steering control signals. In such examples, the two processors 402a,b operate concurrently. However, the SBW system 200 can provide steering control for the vehicle 100 based on only one of the processors 402a,b. As such, if an operating status of one of the processors 402a,b changes to an offline, unavailable, or standby state, the other one of the processors 402a,b continues to provide steering control for the vehicle 100. In such examples, the SBW system 200 can use the second processor 402b instead of the first processor 402a based on an operating status (e.g., an offline, unavailable, or standby status) of the first processor 402a. For example, the power management circuits 404a,b of the separate inductive resolver sensors are independent or switchable. Accordingly, if an operational status of one inductive resolver sensor or its corresponding transmission coil 302a,b are or its corresponding processor 402a,b or ADC 406a,b is to change to an unavailable, offline, or standby state, the other sensor and its corresponding components can still operate based on power provided by the other one of the power management circuits 404a,b.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Digital Signal Processors (DSPs) that may execute first instructions to perform one or more operations and/or functions, XPUs, one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

Example methods, apparatus, systems, and articles of manufacture to implement redundant inductive resolvers are disclosed herein. Further examples and combinations thereof include the following:

Example 1 includes an apparatus comprising a printed circuit board (PCB), the PCB including a first power management circuit coupled to a first transmission coil, a second power management circuit, a first receiver coil including a first coil portion on a first layer of the PCB and a second coil portion on a second layer of the PCB, and a second receiver coil including a third coil portion on the first layer of the PCB and a fourth coil portion on the second layer of the PCB, the second receiver coil in coaxial alignment with the first transmission coil and the first receiver coil.

Example 2 includes the apparatus of example 1, further including a second transmission coil coupled to the second power management circuit.

Example 3 includes the apparatus of example 1 and/or example 2, further including a first processor coupled to the first receiver coil, the first processor to receive a first signal corresponding to the first receiver coil, the first signal based on an angular position of a target coaxially aligned with the first receiver coil and the second receiver coil, and a second processor coupled to the second receiver coil, the second processor to receive a second signal corresponding to the second receiver coil, the second signal based on the angular position of the target.

Example 4 includes the apparatus of any one or more of examples 1-3, wherein the first processor is to determine the angular position of the target based on the first signal from the first receiver coil.

Example 5 includes the apparatus of any one or more of examples 1-4, wherein the second processor is to generate steering control signals instead of the first processor based on an operating status of at least one of the first processor, the first power management circuit, or the first receiver coil.

Example 6 includes the apparatus of any one or more of examples 1-5, including a first via extending between the first and second layers, the first via electrically coupling the first coil portion with the second coil portion of the first receiver coil, and a second via extending between the first and second layers, the second via electrically coupling the third coil portion with the fourth coil portion of the second receiver coil.

Example 7 includes the apparatus of any one or more of examples 1-6, including a third receiver coil including a fifth coil portion on the first layer of the PCB and a sixth coil portion on the second layer of the PCB, and a fourth receiver coil including a seventh coil portion on the first layer of the PCB and an eighth coil portion on the second layer of the PCB, the first and third receiver coils to operate as a first sensor coupled to a first processor, the second and fourth receiver coils to operate as a second sensor coupled to a second processor.

Example 8 includes the apparatus of any one or more of examples 1-7, further including a target coaxially aligned with the first receiver coil and the second receiver coil, the target including multiple lobes in a radial arrangement.

Example 9 includes an apparatus comprising a printed circuit board (PCB), the PCB including first and second power management circuits coupled to respective first and second processors, a first receiver coil in circuit with the first processor, the first receiver coil including a first coil portion on a first layer of the PCB and a second coil portion on a second layer of the PCB, and a second receiver coil in circuit with the second processor and in coaxial alignment with the first receiver coil, the second receiver coil including a third coil portion on the first layer of the PCB and a fourth coil portion on the second layer of the PCB.

Example 10 includes the apparatus of example 9, including a third receiver coil including a fifth coil portion on the first layer of the PCB and a sixth coil portion on the second layer of the PCB, and a fourth receiver coil including a seventh coil portion on the first layer of the PCB and an eighth coil portion on the second layer of the PCB, the first and third receiver coils to operate as a first sensor, the second and fourth receiver coils to operate as a second sensor.

Example 11 includes the apparatus of example 9 and/or example 10, wherein the printed circuit board is a component in a steer-by-wire system of a vehicle.

Example 12 includes the apparatus of example 9, further including a target coaxially aligned with the first receiver coil and the second receiver coil, the target including multiple lobes in a radial arrangement.

Example 13 includes the apparatus of any one or more of examples 9-12, wherein the first processor is to determine an angular position of the target based on a first signal from the first receiver coil.

Example 14 includes a vehicle comprising a target coupled to a steering shaft, a printed circuit board (PCB) in a steer-by-wire system, the PCB including first and second power management circuits coupled to respective first and second analog-to-digital converters, a first receiver coil including a first coil portion on a first layer of the PCB and a second coil portion on a second layer of the PCB, the first receiver coil coupled to the first analog-to-digital converter, and a second receiver coil including a third coil portion on the first layer of the PCB and a fourth coil portion on the second layer of the PCB, the second receiver coil in coaxial alignment with the first receiver coil, the second receiver coil coupled to the second analog-to-digital converter.

Example 15 includes the vehicle of example 14, further including a first processor coupled to the first receiver coil, the first processor to receive a first signal corresponding to the first receiver coil, the first signal based on an angular position of the target coaxially aligned with the first receiver coil and the second receiver coil, and a second processor coupled to the second receiver coil, the second processor to receive a second signal corresponding to the second receiver coil, the second signal based on the angular position of the target.

Example 16 includes the vehicle of example 15 and/or example 15, wherein the first analog-to-digital converter is coupled between the first receiver coil and the first processor, and the second analog-to-digital converter is coupled between the second receiver coil and the second processor, the second analog-to-digital converter is to generate steering control signals instead of the first analog-to-digital converter based on an unavailable operating status of at least one of the first processor, the first power management circuit, the first receiver coil, or the first analog-to-digital converter.

Example 17 includes the vehicle of any one or more of examples 14-16, wherein the first processor is to determine the angular position of the target based on the first signal from the first receiver coil.

Example 18 includes the vehicle of any one or more of examples 14-17, wherein the steer-by-wire system is to use the second processor instead of the first processor based on an operating status of the first processor.

Example 19 includes the vehicle of any one or more of examples 14-18, including a first via extending between the first and second layers, the first via coupling the first coil portion with the second coil portion of the first receiver coil, and a second via extending between the first and second layers, the second via coupling the third coil portion with the fourth coil portion of the second receiver coil.

Example 20 includes the vehicle of any one or more of examples 14-19, including a third receiver coil including a fifth coil portion on the first layer of the PCB and a sixth coil portion on the second layer of the PCB, and a fourth receiver coil including a seventh coil portion on the first layer of the PCB and an eighth coil portion on the second layer of the PCB, the first and third receiver coils to operate as a first sensor, the second and fourth receiver coils to operate as a second sensor.

From the foregoing, it will be appreciated that example systems, apparatus, articles of manufacture, and methods have been disclosed to implement redundant inductive resolvers. Disclosed systems, apparatus, articles of manufacture, and methods provide redundant inductive resolvers that may be used in vehicle SBW systems and that include redundant components such as redundant inductive resolver sensors, redundant processors, redundant power management circuits, and redundant ADCs. In this manner, if an operational status of any of the inductive resolver sensors, processors, power management circuits, or ADCs changes to an offline, unavailable, or standby state, operational ones of the inductive resolver sensors, processors, power management circuits, and ADCs can be used to provide steering control for a vehicle. Disclosed systems, apparatus, articles of manufacture, and methods are accordingly directed to one or more improvement(s) in the operation of a machine such as a SBW system or vehicle.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus comprising:
a printed circuit board (PCB), the PCB including:
a first power management circuit coupled to a first transmission coil;
a second power management circuit;
a first receiver coil including a first coil portion on a first layer of the PCB and a second coil portion on a second layer of the PCB; and
a second receiver coil including a third coil portion on the first layer of the PCB and a fourth coil portion on the second layer of the PCB, the second receiver coil in coaxial alignment with the first transmission coil and the first receiver coil.

2. The apparatus of claim 1, further including a second transmission coil coupled to the second power management circuit.

3. The apparatus of claim 1, further including:
a first processor coupled to the first receiver coil, the first processor to receive a first signal corresponding to the first receiver coil, the first signal based on an angular position of a target coaxially aligned with the first receiver coil and the second receiver coil; and
a second processor coupled to the second receiver coil, the second processor to receive a second signal corresponding to the second receiver coil, the second signal based on the angular position of the target.

4. The apparatus of claim 3, wherein the first processor is to determine the angular position of the target based on the first signal from the first receiver coil.

5. The apparatus of claim 3, wherein the second processor is to generate steering control signals instead of the first processor based on an operating status of at least one of the first processor, the first power management circuit, or the first receiver coil.

6. The apparatus of claim 1, including:
a first via extending between the first and second layers, the first via electrically coupling the first coil portion with the second coil portion of the first receiver coil; and
a second via extending between the first and second layers, the second via electrically coupling the third coil portion with the fourth coil portion of the second receiver coil.

7. The apparatus of claim 1, including:
a third receiver coil including a fifth coil portion on the first layer of the PCB and a sixth coil portion on the second layer of the PCB; and
a fourth receiver coil including a seventh coil portion on the first layer of the PCB and an eighth coil portion on the second layer of the PCB, the first and third receiver coils to operate as a first sensor coupled to a first processor, the second and fourth receiver coils to operate as a second sensor coupled to a second processor.

8. The apparatus of claim 1, further including a target coaxially aligned with the first receiver coil and the second receiver coil, the target including multiple lobes in a radial arrangement.

9. An apparatus comprising:
a printed circuit board (PCB), the PCB including:
first and second power management circuits coupled to respective first and second processors;
a first receiver coil in circuit with the first processor, the first receiver coil including a first coil portion on a first layer of the PCB and a second coil portion on a second layer of the PCB; and
a second receiver coil in circuit with the second processor and in coaxial alignment with the first receiver coil, the second receiver coil including a third coil portion on the first layer of the PCB and a fourth coil portion on the second layer of the PCB.

10. The apparatus of claim 9, including:
a third receiver coil including a fifth coil portion on the first layer of the PCB and a sixth coil portion on the second layer of the PCB; and
a fourth receiver coil including a seventh coil portion on the first layer of the PCB and an eighth coil portion on the second layer of the PCB, the first and third receiver coils to operate as a first sensor, the second and fourth receiver coils to operate as a second sensor.

11. The apparatus of claim 9, wherein the printed circuit board is a component in a steer-by-wire system of a vehicle.

12. The apparatus of claim 9, further including a target coaxially aligned with the first receiver coil and the second receiver coil, the target including multiple lobes in a radial arrangement.

13. The apparatus of claim 12, wherein the first processor is to determine an angular position of the target based on a first signal from the first receiver coil.

14. A vehicle comprising:
a target coupled to a steering shaft;
a printed circuit board (PCB) in a steer-by-wire system, the PCB including:
first and second power management circuits coupled to respective first and second analog-to-digital converters;
a first receiver coil including a first coil portion on a first layer of the PCB and a second coil portion on a second layer of the PCB, the first receiver coil coupled to the first analog-to-digital converter; and
a second receiver coil including a third coil portion on the first layer of the PCB and a fourth coil portion on the second layer of the PCB, the second receiver coil in coaxial alignment with the first receiver coil, the second receiver coil coupled to the second analog-to-digital converter.

15. The vehicle of claim 14, further including:
a first processor coupled to the first receiver coil, the first processor to receive a first signal corresponding to the first receiver coil, the first signal based on an angular position of the target coaxially aligned with the first receiver coil and the second receiver coil; and
a second processor coupled to the second receiver coil, the second processor to receive a second signal corresponding to the second receiver coil, the second signal based on the angular position of the target.

16. The vehicle of claim 15, wherein:
the first analog-to-digital converter is coupled between the first receiver coil and the first processor; and
the second analog-to-digital converter is coupled between the second receiver coil and the second processor, the second analog-to-digital converter is to generate steering control signals instead of the first analog-to-digital converter based on an unavailable operating status of at least one of the first processor, the first power management circuit, the first receiver coil, or the first analog-to-digital converter.

17. The vehicle of claim 15, wherein the first processor is to determine the angular position of the target based on the first signal from the first receiver coil.

18. The vehicle of claim 15, wherein the steer-by-wire system is to use the second processor instead of the first processor based on an operating status of the first processor.

19. The vehicle of claim 14, including:
a first via extending between the first and second layers, the first via coupling the first coil portion with the second coil portion of the first receiver coil; and
a second via extending between the first and second layers, the second via coupling the third coil portion with the fourth coil portion of the second receiver coil.

20. The vehicle of claim 14, including:
a third receiver coil including a fifth coil portion on the first layer of the PCB and a sixth coil portion on the second layer of the PCB; and
a fourth receiver coil including a seventh coil portion on the first layer of the PCB and an eighth coil portion on the second layer of the PCB, the first and third receiver coils to operate as a first sensor, the second and fourth receiver coils to operate as a second sensor.
